(19) United States
(12) Patent Application Publication
(10) Pub. No.: US 2020/0035649 A1
(43) Pub. Date: Jan. 30, 2020

(54) SEMICONDUCTOR PACKAGE

(71) Applicant: Samsung Electronics Co., Ltd., Suwon-si (KR)

(72) Inventors: Ae-nee JANG, Seoul (KR); Nam-gyu BAEK, Suwon-si (KR); Yun-rae CHO, Guri-si (KR); Seung-hun HAN, Hwaseong-si (KR)

(73) Assignee: Samsung Electronics Co., Ltd., Suwon-si (KR)

(21) Appl. No.: 16/376,440

(22) Filed: Apr. 5, 2019

(30) Foreign Application Priority Data
Jul. 25, 2018 (KR) 10-2018-0086767

(51) Int. Cl. H01L 25/065

(52) U.S. Cl. CPC H01L 25/0657; H01L 2225/0651; H01L 2225/06586; H01L 2225/06562; H01L 2225/06517

(57) ABSTRACT

A semiconductor package includes a package substrate, a plurality of external connections under the package substrate, a master chip on the package substrate, at least one slave chip on the master chip, a plurality of first bumps and a plurality of second bumps between the package substrate and the master chip, and a plurality of wires connecting the package substrate to the at least one slave chip. The package substrate includes a plurality of first paths connecting the plurality of first bumps to the plurality of external connections and a plurality of second paths connecting the plurality of second bumps to the plurality of wires. An upper surface of the package substrate includes a first edge and a second edge that extend in a first direction and a third edge and a fourth edge that extend in a second direction.

### CROSS-REFERENCE TO RELATED APPLICATION

This application claims the benefit of Korean Patent Application No. 10-2018-0086767, filed on Jul. 25, 2018, in the Korean Intellectual Property Office, the disclosure of which is incorporated herein in its entirety by reference.

### BACKGROUND

The inventive concepts relate to a semiconductor package, and more particularly, to a semiconductor package including a plurality of semiconductor chips.

In order to achieve a higher density semiconductor package, a semiconductor package including a plurality of stacked semiconductor chips has been developed. The plurality of semiconductor chips may be connected to each other through wire or through silicon vias (TSVs). In addition, the semiconductor chips may be connected to a package substrate by a wire bonding method in which wires are used or a flip chip bonding method in which bumps are used.

### SUMMARY

The inventive concepts provide a semiconductor package having an improved signal integrity (SI) characteristic and/or higher cost competitiveness.

According to an aspect of the inventive concepts, there is provided a semiconductor package including a package substrate, a plurality of external connections under the package substrate, a master chip on the package substrate, at least one slave chip on the master chip, a plurality of first bumps and a plurality of second bumps between the package substrate and the master chip, and a plurality of wires connecting the package substrate and the at least one slave chip. The package substrate includes a plurality of first paths connecting the plurality of first bumps to the plurality of external connections and a plurality of second paths connecting the plurality of second bumps to the plurality of wires. An upper surface of the package substrate includes a first edge and a second edge that extend in a first direction and a third edge and a fourth edge that extend in a second direction.

According to an aspect of the inventive concepts, there is provided a semiconductor package including a package substrate including a plurality of first upper pads, a plurality of lower pads connected to the plurality of first upper pads, a plurality of second upper pads, and a plurality of third upper pads connected to the plurality of second upper pads, a plurality of external connections connected to the plurality of lower pads of the package substrate, a maser chip on the package substrate, at least one slave chip on the master chip, a plurality of first bumps between the plurality of first upper pads of the package substrate and the master chip, a plurality of second bumps between the plurality of second upper pads of the package substrate and the master chip, and a plurality of wires connecting the plurality of third upper pads of the package substrate and the at least one slave chip. An upper surface of the package substrate includes a first edge and a second edge that extend in a first direction and a third edge and a fourth edge that extend in a second direction.

According to an aspect of the inventive concepts, there is provided a semiconductor package including a package substrate, a plurality of external connections under the package substrate, a master chip on the package substrate, at least one slave chip on the master chip, a plurality of first bumps and a plurality of second bumps between the package substrate and the master chip, and a plurality of wires connecting the package substrate and the at least one slave chip. The package substrate includes a plurality of first upper pads that contact the plurality of first bumps and a plurality of second upper pads that contact the plurality of second bumps and the plurality of wires.

### BRIEF DESCRIPTION OF THE DRAWINGS

Embodiments of the inventive concepts will be more clearly understood from the following detailed description taken in conjunction with the accompanying drawings in which:

FIG. 1 is a block diagram illustrating a semiconductor package according to an embodiment of the inventive concepts;

FIG. 2 is a cross-sectional view illustrating a semiconductor package according to an embodiment of the inventive concepts;

FIG. 3 is a bottom view illustrating a master chip and a plurality of bumps according to an embodiment of the inventive concepts;

FIG. 4 is a top view illustrating a top surface of a package substrate according to an embodiment of the inventive concepts;

FIG. 5 is a top view illustrating a top surface of a package substrate according to an embodiment of the inventive concepts;

FIG. 6 is a bottom view illustrating a master chip and a plurality of bumps according to an embodiment of the inventive concepts;

FIG. 7 is a top view illustrating a top surface of a package substrate according to an embodiment of the inventive concepts;

FIG. 8 is a cross-sectional view illustrating a semiconductor package according to an embodiment of the inventive concepts;

FIG. 9 is a cross-sectional view illustrating a semiconductor package according to an embodiment of the inventive concepts;

FIG. 10 is a top view illustrating a top surface of a package substrate according to an embodiment of the inventive concepts; and

FIG. 11 is a top view illustrating a top surface of a package substrate according to an embodiment of the inventive concepts.

### DETAILED DESCRIPTION OF EMBODIMENTS

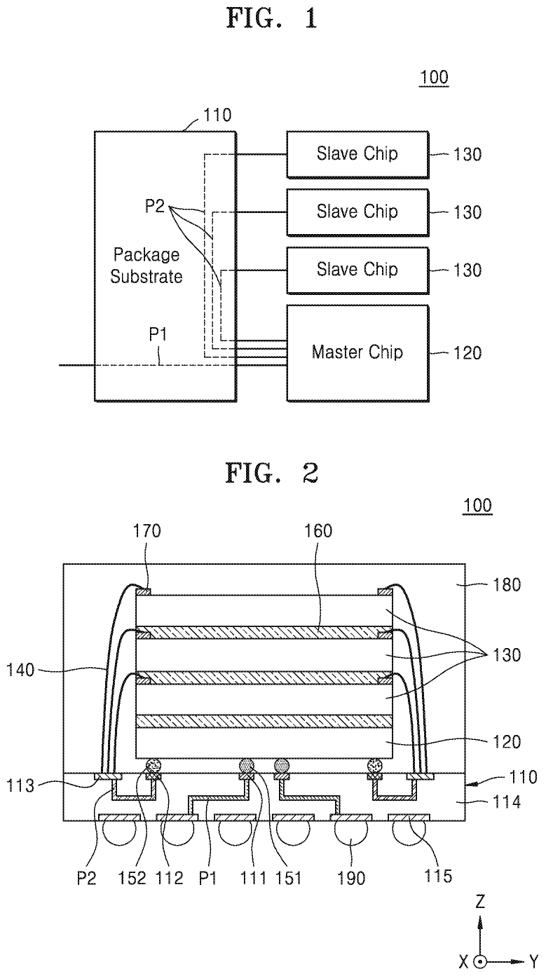

FIG. 1 is a block diagram illustrating a semiconductor package 100 according to an embodiment of the inventive concepts.

Referring to FIG. 1, the semiconductor package 100 according to an embodiment of the inventive concepts may include a package substrate 110, a master chip 120, and/or at least one slave chip 130. In FIG. 1, the semiconductor package 100 is illustrated as including three slave chips 130. However, the number of slave chips 130 included in the semiconductor package 100 may vary. For example, the semiconductor package 100 may include one or more slave chips 130.

The package substrate 110 may include a first path P1 for connecting the master chip 120 to an external connection (not shown) and a second path P2 for connecting the at least one slave chip 130 to the master chip 120. The master chip 120 may be connected to the package substrate 110 by a flip-chip bonding method. The master chip 120 is connected to the external connection through the first path P1 of the package substrate 110 and may be connected to the at least one slave chip 130 through the second path P2 of the package substrate 110. The at least one slave chip 130 may be connected to the package substrate 110 by a wire bonding method. The at least one slave chip 130 may be connected to the master chip 120 through the second path P2 of the package substrate 110. In an embodiment, the first path P1 and the second path P2 are electrical connections.

Each of the master chip 120 and the at least one slave chip 130 may be a memory chip. The memory chip may be, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip. The master chip 120 and the at least one slave chip 130 may be the same kind of memory chips. For example, both the master chip 120 and the at least one slave chip 130 may be DRAM chips.

FIG. 2 is a cross-sectional view illustrating a semiconductor package according to an embodiment of the inventive concepts.

Referring to FIG. 2, the semiconductor package 100 according to an embodiment of the inventive concepts may include the package substrate 110, external connections 190, the master chip 120, the at least one slave chip 130, chip adhesive layers 160, a plurality of bumps 151 and 152, a plurality of wires 140, and/or a molding unit (for example, encapsulant) 180.

The package substrate 110 may include, for example, a printed circuit board (PCB) or a flexible PCB (FPCB). The package substrate 110 may include a base layer 114, a plurality of first upper pads 111, a plurality of second upper pads 112, a plurality of third upper pads 113, a plurality of lower pads 115, a plurality of first paths P1, and/or a plurality of second paths P2. The plurality of first upper pads 111, the plurality of second upper pads 112, and the plurality of third upper pads 113 may be arranged in an upper portion of the base layer 114 and the plurality of lower pads 115 may be arranged in a lower portion of the base layer 114.

The plurality of first upper pads 111 may be connected to the plurality of first bumps 151. The plurality of second upper pads 112 may be connected to the plurality of second bumps 152. The plurality of third upper pads 113 may be connected to the plurality of wires 140. The plurality of lower pads 115 may be connected to the plurality of external connections 190. The plurality of first paths P1 may connect the plurality of first upper pads 111 to the plurality of lower pads 115. The plurality of second paths P2 may connect the plurality of second upper pads 112 to the plurality of third upper pads 113.

The base layer 114 may be formed of epoxy resin, polyester resin, polyimide resin, or a combination of these resins. The base layer 114 may be formed of, for example, glass fiber epoxy composite. The plurality of first upper pads 111, the plurality of second upper pads 112, the plurality of third upper pads 113, the plurality of lower pads 115, the plurality of first paths P1, and/or the plurality of second paths P2 may be formed of a conductive material such as copper (Cu).

The plurality of external connections 190 may connect the semiconductor package 100 to an external circuit. The plurality of external connections 190 may be arranged on the plurality of lower pads 115 of the package substrate 110. The plurality of external connections 190 may be formed of, for example, gold (Au), silver (Ag), Cu, nickel (Ni), tin (Sn), lead (Pb), or a combination of these metals. The external connections 190 may include, for example, solder balls. The plurality of external connections 190 may be arranged on a lower surface of the package substrate 110 in accordance with a joint electron device engineering council (JEDEC) standard. The JEDDEC standard is based on a case in which the master chip 120 is connected to the package substrate 110 not by a wire bonding method, but by a flip-chip bonding method.

The master chip 120 may be arranged on the package substrate 110. A chip pad (not shown) that contacts the plurality of first bumps 151 or the plurality of second bumps 152 may be positioned on a lower surface of the master chip 120. The master chip 120 may be connected to the external connections 190 through the plurality of first bumps 151, the plurality of first upper pads 111, the plurality of first paths P1, and/or the plurality of lower pads 115 of the package substrate 110. The master chip 120 may be connected to the at least one slave chip 130 through the plurality of second bumps 152, the plurality of second upper pads 112, the plurality of second paths P2, the plurality of third upper pads 113 of the package substrate 110, and/or the plurality of wires 140.

The at least one slave chip 130 may be arranged on the master chip 120. When the semiconductor package 100 includes a plurality of slave chips 130, the plurality of slave chips 130 may be stacked on the master chip 120. The at least one slave chip 130 may be connected to the master chip 120 through the plurality of wires 140, the plurality of third upper pads 113, the plurality of second paths P2, the plurality of second upper pads 112, and the plurality of second bumps 152.

Chip adhesive layers 160 may be positioned on lower surfaces of the slave chips 130. Wire bonding pads 170 may be positioned on upper surfaces of the slave chips 130. The chip adhesive layers 160 may include, for example, epoxy resin. The wire bonding pads 170 may include aluminum (Al), Cu, Ag, Au, or a combination of the above metals.

The plurality of bumps 151 and 152 may be positioned between the master chip 120 and the package substrate 110. That is, the plurality of bumps 151 and 152 may be attached to the lower surface of the master chip 120. The plurality of bumps 151 and 152 may include the plurality of first bumps 151 and the plurality of second bumps 152. The plurality of first bumps 151 connect the master chip 120 to the plurality of first upper pads 111 of the package substrate 110. The plurality of second bumps 152 connect the master chip 120 to the plurality of second upper pads 112 of the package substrate 110. The plurality of bumps 151 and 152 may be formed of Au, Ag, Cu, Ni, Sn, Pb, or a combination of the above metals. The plurality of bumps 151 and 152 may include, for example, solder balls.

The plurality of wires 140 may connect the wire bonding pads 170 on the at least one slave chip 130 to the plurality of third upper pads 113 of the package substrate 110. The plurality of wires 140 may include Al, Cu, Ag, Au, or a combination of the above metals.

The molding unit (for example, encapsulant) 180 covers an upper surface of the package substrate 110 and may wrap the master chip 120 and the at least one slave chip 130. The molding unit 180 may include thermosetting resin, thermoplastic resin, ultraviolet (UV) curing resin, or a combination of the above resins. The molding unit 180 may include, for example, epoxy resin, silicon resin, or a combination of the above resins. The molding unit 180 may include, for example, epoxy mold compound (EMC).

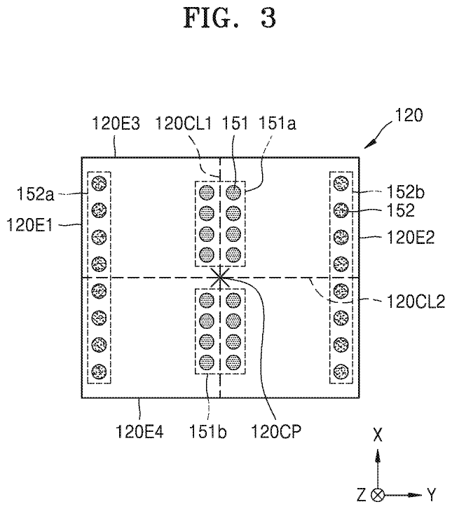

FIG. 3 is a bottom view illustrating a master chip and a plurality of bumps according to an embodiment of the inventive concepts.

Referring to FIG. 3, the lower surface of the master chip 120 may be approximately rectangular or square. That is, the lower surface of the master chip 120 may include four edges, namely, first, second, third, and fourth edges 120E1, 120E2, 120E3, and 120E4. The first edge 120E1 and the second edge 120E2 of the lower surface of the master chip 120 may extend in a first direction X. The third edge 120E3 and the fourth edge 120E4 of the lower surface of the master chip 120 may extend in a second direction Y. The first direction X may be perpendicular to the second direction Y.

A first central line 120CL1 of the lower surface of the master chip 120 extends to run parallel with the first edge 120E1 and the second edge 120E2 of the lower surface of the master chip 120 in the first direction X and may pass a central point 120CP of the lower surface of the master chip 120. A distance from the first central line 120CL1 of the lower surface of the master chip 120 to the first edge 120E1 of the lower surface of the master chip 120 in the second direction Y may be the same as a distance from the first central line 120CL1 of the lower surface of the master chip 120 to the second edge 120E2 of the lower surface of the master chip 120 in the second direction Y.

A second central line 120CL2 of the lower surface of the master chip 120 extends to run parallel with the third edge 120E3 and the fourth edge 120E4 of the lower surface of the master chip 120 in the second direction Y and may pass the central point 120CP of the lower surface of the master chip 120. A distance from the second central line 120CL2 of the lower surface of the master chip 120 to the third edge 120E3 of the lower surface of the master chip 120 in the first direction X may be the same as a distance from the second central line 120CL2 of the lower surface of the master chip 120 to the fourth edge 120E4 of the lower surface of the master chip 120 in the first direction X.

The first central line 120CL1 and the second central line 120CL2 of the lower surface of the master chip 120 may intersect the central point 120CP of the lower surface of the master chip 120. That is, a distance from the central point 120CP of the lower surface of the master chip 120 to the first edge 120E1 of the lower surface of the master chip 120 in the second direction Y is the same as a distance from the central point 120CP of the lower surface of the master chip 120 to the second edge 120E2 of the lower surface of the master chip 120 in the second direction Y. A distance from the central point 120CP of the lower surface of the master chip 120 to the third edge 120E3 of the lower surface of the master chip 120 in the first direction X may be the same as a distance from the central point 120CP of the lower surface of the master chip 120 to the fourth edge 120E4 of the lower surface of the master chip 120 in the first direction X.

The plurality of first bumps 151 may include a first group 151a and a second group 151b. Among the plurality of first bumps 151, the first group 151a may be closer to the third edge 120E3 of the lower surface of the master chip 120 than to the fourth edge 120E4 of the lower surface of the master chip 120. On the other hand, among the plurality of first bumps 151, the second group 151b may be closer to the fourth edge 120E4 of the lower surface of the master chip 120 than to the third edge 120E3 of the lower surface of the master chip 120. Among the plurality of first bumps 151, the first group 151a may be configured to transmit signals different from signals transmitted by the second group 151b. For example, the first group 151a among the plurality of first bumps 151 is configured to transmit data signals and the second group 151b among the plurality of first bumps 151 may be configured to transmit address signals and clock signals.

The plurality of first bumps 151 may be closer to the first central line 120CL1 of the lower surface of the master chip 120 than the plurality of second bumps 152.

At least one of the plurality of first bumps 151 may be arranged in the central portion of the lower surface of the master chip 120. For example, at least one of the plurality of first bumps 151 may be closer to the first central line 120CL1 of the lower surface of the master chip 120 than to the first edge 120E1 and the second edge 120E2 of the lower surface of the master chip 120. In addition, at least one of the plurality of first bumps 151 may be closer to the second central line 120CL2 of the lower surface of the master chip 120 than to the third edge 120E3 and the fourth edge 120E4 of the lower surface of the master chip 120.

In some embodiments, all the plurality of first bumps 151 may be arranged in the central portion of the lower surface of the master chip 120. For example, all the plurality of first bumps 151 may be closer to the first central line 120CL1 of the lower surface of the master chip 120 than to the first edge 120E1 and the second edge 120E2 of the lower surface of the master chip 120.

The plurality of second bumps 152 may be arranged at edge portions of the lower surface of the master chip 120. In some embodiments, the plurality of second bumps 152 may be adjacent to the first edge 120E1 or the second edge 120E2 of the lower surface of the master chip 120. That is, among the plurality of second bumps 152, the first group 152a may be closer to the first edge 120E1 of the lower surface of the master chip 120 than to the first central line 120CL1 of the lower surface of the master chip 120. In addition, among the plurality of second bumps 152, the second group 152b may be closer to the second edge 120E2 of the lower surface of the master chip 120 than to the first central line 120CL1 of the lower surface of the master chip 120. In some embodiments, the plurality of second bumps 152 may be arranged along the first edge 120E1 and the second edge 120E2 of the lower surface of the master chip 120. That is, among the plurality of second bumps 152, the first group 152a and the second group 152b may be arranged in the first direction X.

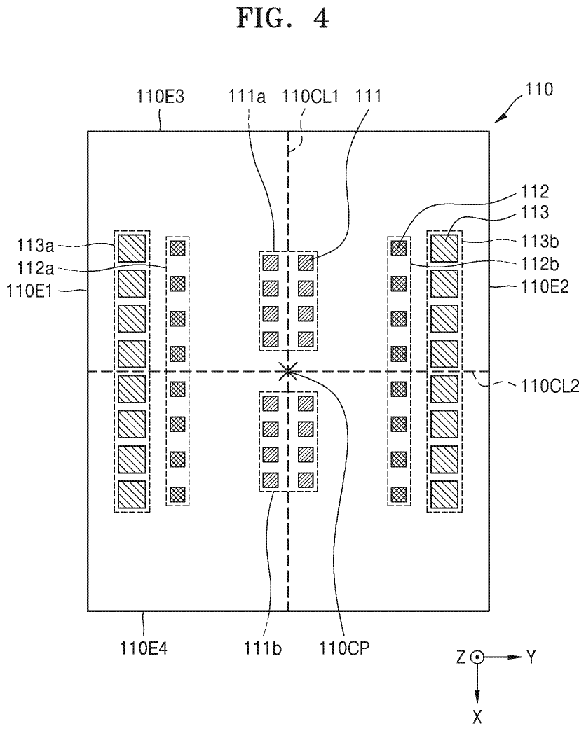

FIG. 4 is a top view illustrating a top surface of a package substrate according to an embodiment of the inventive concepts.

Referring to FIG. 4, an upper surface of a package substrate may be approximately rectangular or square. That is, the upper surface of the package substrate 110 may include four edges, namely, first, second, third, and fourth edges 110E1, 110E2, 110E3, and 110E4. The first edge 110E1 and the second edge 110E2 of the upper surface of the package substrate 110 may extend in the first direction X. The third edge 110E3 and the fourth edge 110E4 of the upper surface of the package substrate 110 may extend in the second direction Y.

A first central line 110CL1 of the upper surface of the package substrate 110 extends to run parallel with the first edge 110E1 and the second edge 110E2 of the upper surface of the package substrate 110 in the first direction X and may pass a central point 110CP of the upper surface of the package substrate 110. A distance from the first central line 110CL1 of the upper surface of the package substrate 110 to the first edge 110E1 of the upper surface of the package substrate 110 in the second direction Y may be the same as a distance from the first central line 110CL1 of the upper surface of the package substrate 110 to the second edge 110E2 of the upper surface of the package substrate 110 in the second direction Y.

A second central line 110CL2 of the upper surface of the package substrate 110 extends to run parallel with the third edge 110E3 and the fourth edge 110E4 of the upper surface of the package substrate 110 in the second direction Y and may pass the central point 110CP of the upper surface of the package substrate 110. A distance from the second central line 110CL2 of the upper surface of the package substrate 110 to the third edge 110E3 of the upper surface of the package substrate 110 in the first direction X may be the same as a distance from the second central line 110CL2 of the upper surface of the package substrate 110 to the fourth edge 110E4 of the upper surface of the package substrate 110 in the first direction X.

The first central line 110CL1 and the second central line 110CL2 of the upper surface of the package substrate 110 may intersect the central point 110CP of the upper surface of the package substrate 110. That is, a distance from the central point 110CP of the upper surface of the package substrate 110 to the first edge 110E1 of the upper surface of the package substrate 110 in the second direction Y is the same as a distance from the central point 110CP of the upper surface of the package substrate 110 to the second edge 110E2 of the upper surface of the package substrate 110 in the second direction Y. A distance from the central point 110CP of the upper surface of the package substrate 110 to the third edge 110E3 of the upper surface of the package substrate 110 in the first direction X may be the same as a distance from the central point 110CP of the upper surface of the package substrate 110 to the fourth edge 110E4 of the upper surface of the package substrate 110 in the first direction X.

The plurality of first upper pads 111 may include a first group 111a and a second group 111b. Among the plurality of upper pads 111, the first group 111a may be closer to the third edge 110E3 of the upper surface of the package substrate 110 than to the fourth edge 110E4 of the upper surface of the package substrate 110. Among the plurality of first upper pads 111, the second group 111b may be closer to the fourth edge 110E4 of the upper surface of the package substrate 110 than to the third edge 110E3 of the upper surface of the package substrate 110.

The plurality of first upper pads 111 may be closer to the first central line 110CL1 of the upper surface of the package substrate 110 than the plurality of second upper pads 112. In addition, the plurality of first upper pads 111 may be closer to the first central line 110CL1 of the upper surface of the package substrate 110 than the plurality of third upper pads 113. In addition, the plurality of second upper pads 112 may be closer to the first central line 110CL1 of the upper surface of the package substrate 110 than the plurality of third upper pads 113.

The plurality of first upper pads 111 may be arranged in the central portion of the package substrate 110. That is, the plurality of first upper pads 111 may be closer to the first central line 110CL1 of the upper surface of the package substrate 110 than to the first edge 110E1 and the second edge 110E2 of the upper surface of the package substrate 110.

The plurality of third upper pads 113 may be arranged at edge portions of the package substrate 110. In some embodiments, the plurality of third upper pads 113 may be adjacent to the first edge 110E1 or the second edge 110E2 of the upper surface of the package substrate 110. That is, among the plurality of third upper pads 113, a first group 113a may be closer to the first edge 110E1 of the upper surface of the package substrate 110 than to the first central line 110CL1 of the upper surface of the package substrate 110. In addition, among the plurality of third upper pads 113, a second group 113b may be closer to the second edge 110E2 of the upper surface of the package substrate 110 than to the first central line 110CL1 of the upper surface of the package substrate 110. In some embodiments, the plurality of third upper pads 113 may be arranged along the first edge 110E1 and the second edge 110E2 of the upper surface of the package substrate 110. That is, among the plurality of third upper pads 113, the first group 113a and the second group 113b may be arranged in the first direction X.

In some embodiments, the plurality of second upper pads 112 may be arranged at edge portions of the package substrate 110. In some embodiments, the plurality of second upper pads 112 may be adjacent to the first edge 110E1 or the second edge 110E2 of the upper surface of the package substrate 110. That is, among the plurality of second upper pads 112, a first group 112a may be closer to the first edge 110E1 of the upper surface of the package substrate 110 than to the first central line 110CL1 of the upper surface of the package substrate 110. In addition, among the plurality of second upper pads 112, a second group 112b may be closer to the second edge 110E2 of the upper surface of the package substrate 110 than to the first central line 110CL1 of the upper surface of the package substrate 110. In some embodiments, the plurality of second upper pads 112 may be arranged along the first edge 110E1 and the second edge 110E2 of the upper surface of the package substrate 110. That is, among the plurality of second upper pads 112, the first group 112a and the second group 112b may be arranged in the first direction X.

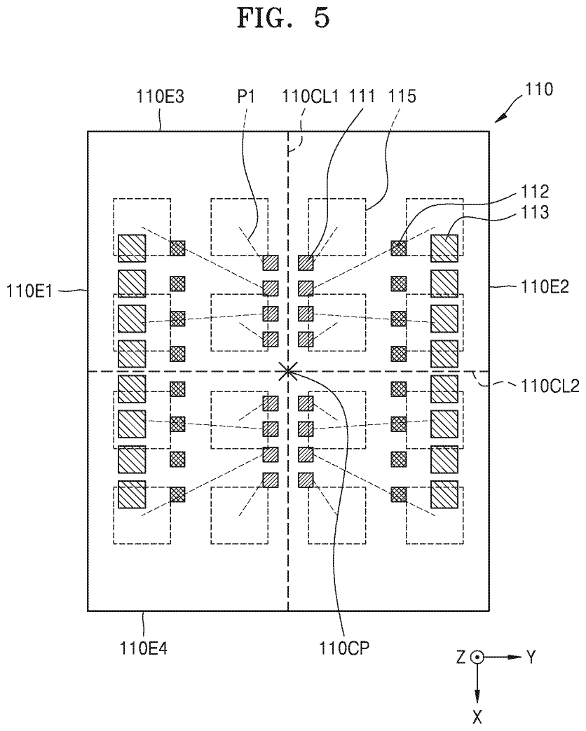

FIG. 5 is a top view illustrating a top surface of a package substrate according to an embodiment of the inventive concepts.

Referring to FIG. 5, in order to illustrate a connection relationship between the plurality of first upper pads 111 and the plurality of lower pads 115 of the package substrate 110, the plurality of lower pads 115 on the lower surface of the package substrate 110 and a plurality of first paths P1 in the package substrate 110 are illustrated together. For convenience sake, the plurality of first paths P1 are illustrated as being linear. However, the plurality of first paths P1 may actually have more complicated shapes.

The plurality of first paths P1 connect the plurality of first upper pads 111 to the plurality of lower pads 115. Since the plurality of first upper pads 111 are positioned in the central portion of the upper surface of the package substrate 110, that is, since the plurality of first upper pads 111 are arranged to be closer to the first central line 110CL1 of the package substrate 110 than to the first edge 110E1 and the second edge 110E2 of the upper surface of the package substrate 110, lengths of the plurality of first paths P1 may be less than a case in which the plurality of first upper pads 111 are positioned at edges of the upper surface of the package substrate 110. Therefore, signal integrity (SI) of the semiconductor package 100 (refer to FIG. 2) according to an embodiment of the inventive concepts may improve.

Referring to FIG. 2, the plurality of lower pads 115 and the plurality of external connections 190 are arranged in accordance with the JEDEC standard defined based on a flip chip. Therefore, when the master chip 120 is connected to the package substrate 110 by flip chip bonding, the lengths of the plurality of first paths P1 may be reduced or minimized compared to a case in which the master chip 120 is connected to the package substrate 110 by wire bonding. Therefore, the SI of the semiconductor package 100 according to an embodiment of the inventive concepts may improve.

On the other hand, the at least one slave chip 130 is connected to the plurality of third upper pads 113 of the package substrate 110 through the plurality of wires 140, which are inexpensive. Therefore, the semiconductor package 100 according to an embodiment of the inventive concepts may have high cost competitiveness.

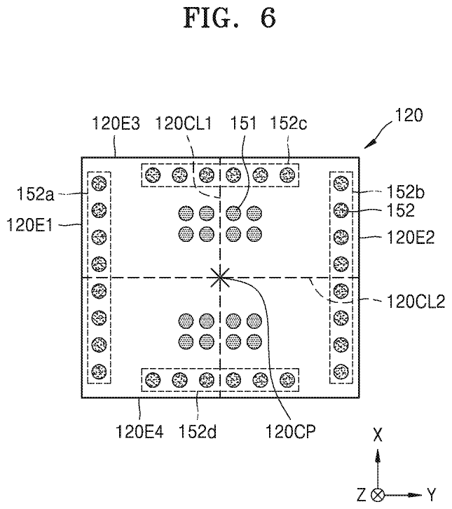

FIG. 6 is a bottom view illustrating a master chip and a plurality of bumps according to an embodiment of the inventive concepts.

Referring to FIG. 6, the plurality of first bumps 151 may be closer to the central point 120CP of the lower surface of the master chip 120 than the plurality of second bumps 152. In addition, the plurality of second bumps 152 may further include a third group 152c and a fourth group 152d. Among the plurality of second bumps 152, the third group 152c may be adjacent to the third edge 120E3 of the lower surface of the master chip 120. That is, among the plurality of second bumps 152, the third group 152c may be closer to the third edge 120E3 of the lower surface of the master chip 120 than to the second central line 120CL2 of the lower surface of the master chip 120. Among the plurality of second bumps 152, the fourth group 152d may be adjacent to the fourth edge 120E4 of the lower surface of the master chip 120. That is, among the plurality of second bumps 152, the fourth group 152d may be closer to the fourth edge 120E4 of the lower surface of the master chip 120 than to the second central line 120CL2 of the lower surface of the master chip 120. In some embodiments, among the plurality of second bumps 152, the third group 152c and the fourth group 152d may be respectively arranged along the third edge 120E3 and the fourth edge 120E4 of the lower surface of the master chip 120. That is, among the plurality of second bumps 152, the third group 152c and the fourth group 152d may be arranged in the second direction Y.

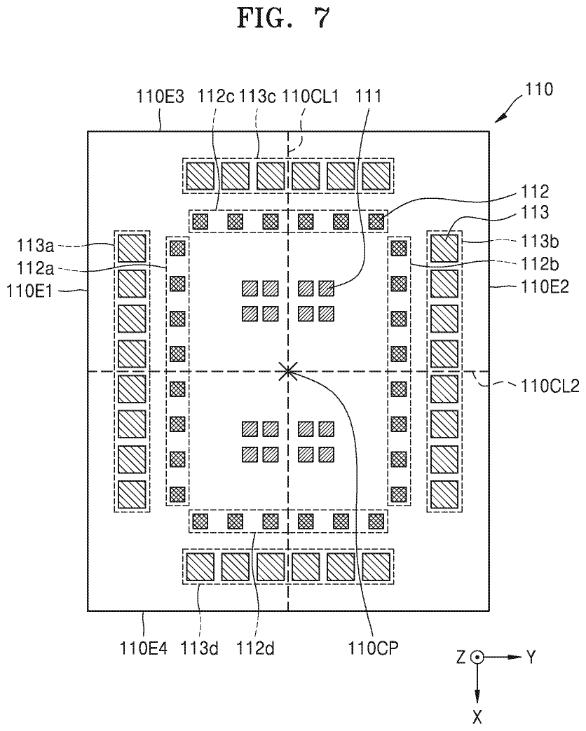

FIG. 7 is a top view illustrating a top surface of a package substrate according to an embodiment of the inventive concepts.

Referring to FIG. 7, the plurality of second upper pads 112 further include a third group 112c and a fourth group 112d. Among the plurality of second upper pads 112, the third group 112c may be adjacent to the third edge 110E3 of the upper surface of the package substrate 110. That is, among the plurality of second upper pads 112, the third group 112c may be closer to the third edge 110E3 of the upper surface of the package substrate 110 than to the second central line 110CL2 of the upper surface of the package substrate 110. In addition, among the plurality of second upper pads 112, the fourth group 112d may be adjacent to the fourth edge 110E4 of the upper surface of the package substrate 110. That is, among the plurality of second upper pads 112, the fourth group 112d may be closer to the fourth edge 110E4 of the upper surface of the package substrate 110 than to the second central line 110CL2 of the upper surface of the package substrate 110.

In addition, the plurality of third upper pads 113 further include a third group 113c and a fourth group 113d. Among the plurality of third upper pads 113, the third group 113c may be adjacent to the third edge 110E3 of the upper surface of the package substrate 110. That is, among the plurality of third upper pads 113, the third group 113c may be closer to the third edge 110E3 of the upper surface of the package substrate 110 than to the second central line 110CL2 of the upper surface of the package substrate 110. In addition, among the plurality of third upper pads 113, the fourth group 113d may be adjacent to the fourth edge 110E4 of the upper surface of the package substrate 110. That is, among the plurality of third upper pads 113, the fourth group 113d may be closer to the fourth edge 110E4 of the upper surface of the package substrate 110 than to the second central line 110CL2 of the upper surface of the package substrate 110.

In some embodiments, the plurality of first upper pads 111 may be closer to the central point 110CP of the upper surface of the package substrate 110 than the plurality of second upper pads 112. In addition, the plurality of first upper pads 111 may be closer to the central point 110CP of the upper surface of the package substrate 110 than the plurality of third upper pads 113.

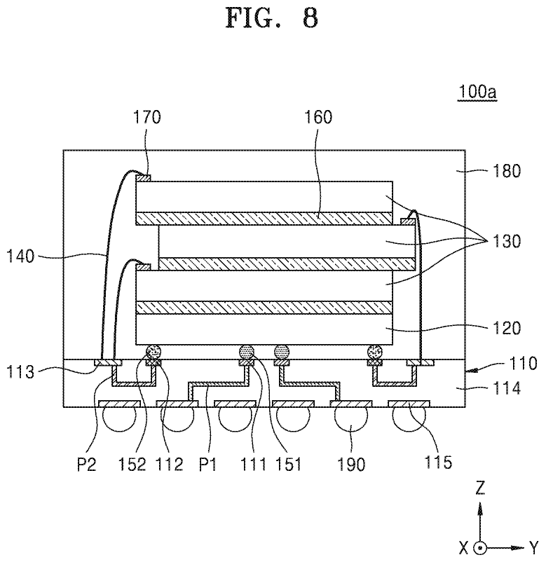

FIG. 8 is a cross-sectional view illustrating a semiconductor package according to an embodiment of the inventive concepts. Hereinafter, a difference between the semiconductor package according to the embodiment of FIG. 2 and the semiconductor package according to the embodiment of FIG. 8 will be described.

Referring to FIG. 8, the at least one slave chip 130 may be stacked in zigzags.

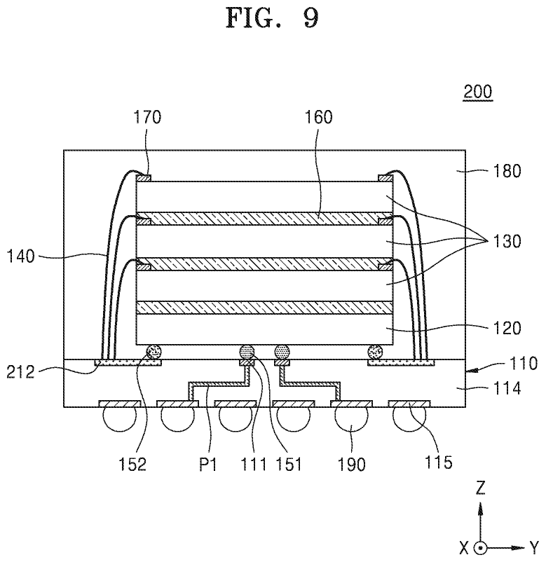

FIG. 9 is a cross-sectional view illustrating a semiconductor package according to an embodiment of the inventive concepts. Hereinafter, a difference between the semiconductor package according to the embodiment of FIG. 2 and the semiconductor package according to the embodiment of FIG. 9 will be described.

Referring to FIG. 9, the plurality of wires 140 and the plurality of second bumps 152 may contact a plurality of second upper pads 212 of the package substrate 110. That is, the at least one slave chip 130 may be connected to the master chip 120 through the plurality of wires 140, the plurality of second upper pads 212, and/or the plurality of second bumps 152.

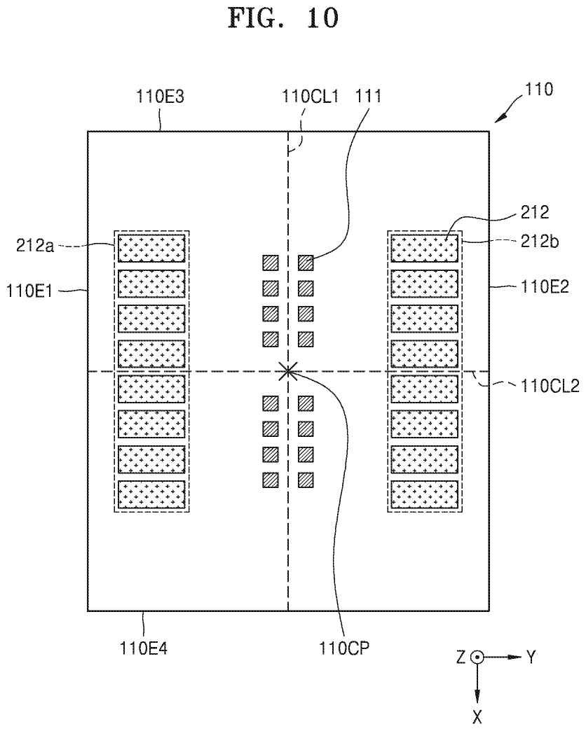

FIG. 10 is a top view illustrating a top surface of a package substrate according to an embodiment of the inventive concepts. Hereinafter, a difference between the embodiment of FIG. 4 and the embodiment of FIG. 10 will be described.

Referring to FIG. 10, the plurality of second upper pads 212 may be adjacent to the first edge 110E1 or the second edge 110E2 of the upper surface of the package substrate 110. That is, among the plurality of second upper pads 212, a first group 212a may be closer to the first edge 110E1 of the upper surface of the package substrate 110 than to the first central line 110CL1 of the upper surface of the package substrate 110. In addition, among the plurality of second upper pads 212, a second group 212b may be closer to the second edge 110E2 of the upper surface of the package substrate 110 than to the first central line 110CL1 of the upper surface of the package substrate 110. In some embodiments, the plurality of second upper pads 212 may be arranged along the first edge 110E1 and the second edge 110E2 of the upper surface of the package substrate 110. That is, among the plurality of second upper pads 212, the first group 112a and the second group 112b may be arranged in the first direction X.

Areas of the plurality of second upper pads 212 may be greater than those of the plurality of first upper pads 111.

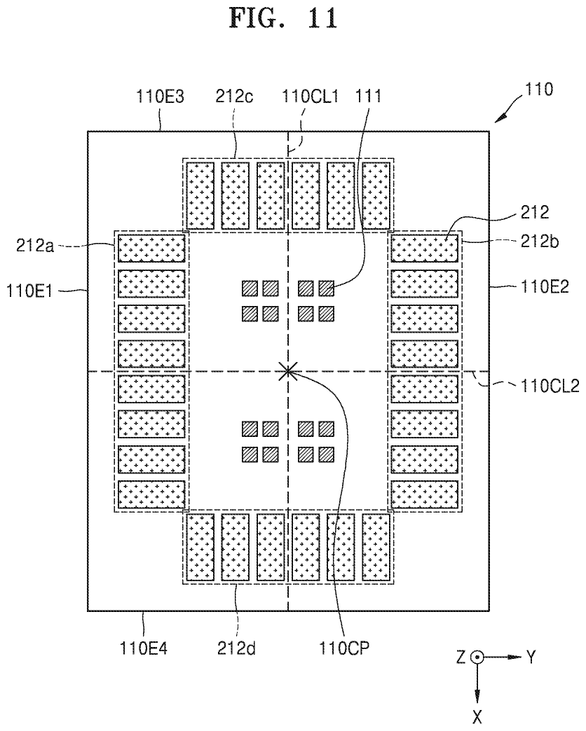

FIG. 11 is a top view illustrating a top surface of a package substrate according to an embodiment of the inventive concepts. Hereinafter, a difference between the embodiment of FIG. 10 and the embodiment of FIG. 11 will be described.

Referring to FIG. 11, the plurality of second upper pads 212 further include a third group 212c and a fourth group 212d. Among the plurality of second upper pads 212, the third group 212c may be adjacent to the third edge 110E3 of the upper surface of the package substrate 110. That is, among the plurality of second upper pads 212, the third group 212c may be closer to the third edge 110E3 of the upper surface of the package substrate 110 than to the second central line 110CL2 of the upper surface of the package substrate 110. In addition, among the plurality of second upper pads 212, the fourth group 212d may be adjacent to the fourth edge 110E4 of the upper surface of the package substrate 110. That is, among the plurality of second upper pads 212, the fourth group 212d may be closer to the fourth edge 110E4 of the upper surface of the package substrate 110 than to the second central line 110CL2 of the upper surface of the package substrate 110.

While the inventive concepts have been particularly shown and described with reference to embodiments thereof, it will be understood that various changes in form and details may be made therein without departing from the spirit and scope of the following claims.

What is claimed is:

1. A semiconductor package comprising:
a package substrate;
a plurality of external connections under the package substrate;
a master chip on the package substrate;
at least one slave chip on the master chip;
a plurality of first bumps and a plurality of second bumps between the package substrate and the master chip; and
a plurality of wires connecting the package substrate to the at least one slave chip,
wherein the package substrate comprises a plurality of first paths connecting the plurality of first bumps to the plurality of external connections and a plurality of second paths connecting the plurality of second bumps to the plurality of wires, and
wherein an upper surface of the package substrate comprises a first edge and a second edge that extend in a first direction and a third edge and a fourth edge that extend in a second direction.

2. The semiconductor package of claim 1, wherein the master chip is connected to the plurality of external connections through the plurality of first bumps and the plurality of first paths of the package substrate.

3. The semiconductor package of claim 1, wherein the at least one slave chip is connected to the master chip through the plurality of wires, the plurality of second paths of the package substrate, and the plurality of second bumps.

4. The semiconductor package of claim 1, wherein the plurality of first bumps are closer to a first central line that extends in the first direction and passes a central point of a lower surface of the master chip than the plurality of second bumps.

5. The semiconductor package of claim 1, wherein the plurality of first bumps are closer to a central point of the lower surface of the master chip than the plurality of second bumps.

6. The semiconductor package of claim 1, wherein at least one of the plurality of first bumps is closer to a first central line that extends in the first direction and passes a central point of a lower surface of the master chip than to the first edge and the second edge of the lower surface of the master chip.

7. The semiconductor package of claim 1, wherein at least one of the plurality of first bumps is closer to a second central line that extends in the second direction and passes a central point of a lower surface of the master chip than to the third edge and the fourth edge of the lower surface of the master chip.

8. The semiconductor package of claim 1,
wherein second bumps of a first group among the plurality of second bumps are closer to the first edge of a lower surface of the master chip than to a first central line that extends in the first direction and passes a central point of the lower surface of the master chip, and
wherein second bumps of a second group among the plurality of second bumps are closer to the second edge of the lower surface of the master chip than to the first central line of the lower surface of the master chip.

9. The semiconductor package of claim 8, wherein the second bumps of the first group and the second bumps of the second group are arranged in the first direction.

10. The semiconductor package of claim 1,
wherein second bumps of a third group among the plurality of second bumps are closer to the third edge of a lower surface of the master chip than to a second central line that extends in the second direction and passes a central point of the lower surface of the master chip, and
wherein second bumps of a fourth group among the plurality of second bumps are closer to the fourth edge of the lower surface of the master chip than to the second central line of the lower surface of the master chip.

11. The semiconductor package of claim 10, wherein the second bumps of the third group and second bumps of the fourth group are arranged in the second direction.

12. A semiconductor package comprising:
a package substrate including a plurality of first upper pads, a plurality of lower pads connected to the plurality of first upper pads, a plurality of second upper pads, and a plurality of third upper pads connected to the plurality of second upper pads;
a plurality of external connections connected to the plurality of lower pads of the package substrate;
a master chip on the package substrate;
at least one slave chip on the master chip;
a plurality of first bumps between the plurality of first upper pads of the package substrate and the master chip;
a plurality of second bumps between the plurality of second upper pads of the package substrate and the master chip; and
a plurality of wires connecting the plurality of third upper pads of the package substrate to the at least one slave chip,
wherein an upper surface of the package substrate includes a first edge and a second edge that extend in a first direction and a third edge and a fourth edge that extend in a second direction.

13. The semiconductor package of claim 12, wherein the plurality of first upper pads are closer to a first central line that extends in the first direction and passes a central point of an upper surface of the package substrate than the plurality of second upper pads.

14. The semiconductor package of claim 12, wherein the plurality of first upper pads are closer to a first central line that extends in the first direction and passes a central point of an upper surface of the package substrate than the plurality of third upper pads.

15. The semiconductor package of claim 12, wherein the plurality of second upper pads are closer to a first central line that extends in the first direction and passes a central point of an upper surface of the package substrate than the plurality of third upper pads.

16. The semiconductor package of claim 12,
wherein third upper pads of a first group among the plurality of third upper pads are closer to the first edge of an upper surface of the package substrate than to a first central line that extends in the first direction and passes a central point of the upper surface of the package substrate,
wherein third upper pads of a second group among the plurality of third upper pads are closer to the second edge of an upper surface of the package substrate than to the first central line on the upper surface of the package substrate.

17. The semiconductor package of claim 12,
wherein third upper pads of a third group among the plurality of third upper pads are closer to a third edge of an upper surface of the package substrate than to a second central line that extends in the second direction and passes a central point of the upper surface of the package substrate,
wherein third upper pads of a fourth group among the plurality of third upper pads are closer to the fourth edge of an upper surface of the package substrate than to the second central line on the upper surface of the package substrate.

18. The semiconductor package of claim 12, wherein the plurality of first upper pads are closer to a central point of an upper surface of the package substrate than the plurality of third upper pads.

19. A semiconductor package comprising:
a package substrate;
a plurality of external connections under the package substrate;
a master chip on the package substrate;
at least one slave chip on the master chip;
a plurality of first bumps and a plurality of second bumps between the package substrate and the master chip; and
a plurality of wires connecting the package substrate to the at least one slave chip,
wherein the package substrate comprises a plurality of first upper pads that contact the plurality of first bumps and a plurality of second upper pads that contact the plurality of second bumps and the plurality of wires.

20. The semiconductor package of claim 19, wherein a size of each of the plurality of second upper pads is greater than a size of each of the plurality of first upper pads.
